(19) United States
(12) Patent Application Publication
(10) Pub. No.: US 2024/0206089 A1
(43) Pub. Date: Jun. 20, 2024

(54) ATTACHMENT APPARATUSES

(71) Applicant: Hung Cheong Tang, Hong Kong (CN)

(72) Inventor: Hung Cheong Tang, Hong Kong (CN)

(21) Appl. No.: 18/287,308

(22) PCT Filed: Apr. 25, 2022
(86) PCT No.: PCT/IB2022/053809

§ 371 Date: Oct. 18, 2023

(30) Foreign Application Priority Data
Apr. 23, 2021 (HK) 32021029831.3

(51) Int. Cl. H05K 5/02

(52) U.S. Cl. CPC H05K 5/0217

(57) ABSTRACT

An apparatus (100) for attaching to a support surface (112, 122) by means of a receptacle (179) mounted in the support surface (112, 122). The apparatus (100) comprises attachment means for attaching to the receptacle (179), engagement means for making frictional engagement with the receptacle (179), a stop mechanism to prevent detachment of the apparatus (100) from the receptacle (179), and a de-actuation mechanism to de-actuate the stop mechanism to allow detachment of the apparatus (100) in a withdrawal direction by overcoming frictional retention forces.

### FIELD

The present disclosure relates to attachable apparatuses which are detachable from a support surface, and also relates to an assembly comprising an attachable apparatus and a receptacle for mounting the attachable apparatus on a support surface.

### BACKGROUND

Arrangements such as devices and apparatuses are required to be installed or removed from a difficult-to-access location such as a narrow space which are beyond the reach of a human arm and which are too narrow for access by a service personnel. It would be advantageous if arrangements to alleviate problems of having a device or apparatus mounted at or dismounted from a difficult-to-access location.

### SUMMARY OF DISCLOSURE

An attachment apparatus comprising a main housing and an attachment arrangement for securing the main housing to a surface-mountable receptacle is disclosed. The main housing is configured to move along a first direction to enter into detachable engagement with the receptacle at a retention position relative to the receptacle, the first direction being an insertion direction defined by a first axis and a first plane. The main housing comprises a first portion, a second portion, and a peripheral portion interconnecting the first portion and the second portion which cooperate to define an internal compartment for accommodating items including circuitries, components and/or mechanisms. The attachment arrangement comprises a stop mechanism which is operable between an actuated state and a de-actuated state, and a de-actuation mechanism which is operable to de-actuate the stop mechanism. The stop mechanism is configured to impede movement of the main housing in a withdrawal direction relative to the second part when in the actuated state, the withdrawal direction being opposite to the insertion direction. The stop mechanism is configured to not to impede movement of the main housing in the withdrawal direction when in the de-actuated state, and the stop mechanism is in the de-actuated state when de-actuated. The stop mechanism is configured to be de-actuated by application of a de-actuation force through the main housing to operate the de-actuation mechanism, the de-actuation force being in the insertion direction.

### FIGURES

The present disclosure will be described by way of example with reference to the accompany figures, in which:

FIG. 1A is a front perspective view of an example assembly of the present disclosure,

FIGS. 1B and 1C are side perspective views of the assembly of FIG. 1A,

FIG. 2A is a top front perspective view of an example apparatus of the present disclosure,

FIGS. 2B and 2C are, respectively, top rear perspective and rear bottom perspective view of the example apparatus,

FIG. 2D is an exploded view of the example apparatus,

FIGS. 3A, 3B and 3C are, respectively, top front perspective, top plan and bottom plan views of an example receptacle,

FIG. 3D is a bottom perspective view of the receptacle showing component parts detached,

FIG. 4A is a front perspective view of an example assembly of the present disclosure,

FIGS. 4B and 4C are side perspective views of the assembly of FIG. 4A,

FIG. 5A is a top front perspective view of an example apparatus of the present disclosure,

FIGS. 5B and 5C are, respectively, top rear perspective and rear bottom perspective view of the example apparatus,

FIG. 5D is an exploded view of the example apparatus,

FIG. 5E shows an example de-actuation mechanism of the apparatus of FIG. 5A,

FIG. 5F is a sectioned view of the de-actuation mechanism of FIG. 5E,

FIG. 5G is an exploded view of the de-actuation mechanism,

FIG. 5H is an exploded view showing the coupling port,

FIGS. 6A and 6B are, respectively, top and bottom perspective views of a receptacle for the apparatus of FIG. 5A,

FIG. 7A is a cross-sectional view of the apparatus of FIG. 1A in a locked state,

FIG. 7B is a cross-sectional view of the apparatus of FIG. 1A in an un-locked state,

FIG. 7C1 is cross-sectional view of the receptacle of FIG. 1A,

FIG. 7C2 is cross-sectional view of the apparatus of FIG. 1A in its natural state,

FIG. 7D is a cross-sectional view of the assembly in the assembled but unlocked configuration,

FIG. 8 shows an example tool for installation and removal of the apparatus, and

FIG. 9 show an example application of the apparatuses.

### DESCRIPTION

An example attachment assembly comprises a first part and a second part which are in detachable engagement. The second part is configured to be secured on a support surface. When the second part is mounted on a support surface, the second part of the mounted attachment assembly is intermediate the first part and the support surface, the weight of the first part is borne by the second part, and the weight of the assembly is borne by the support surface.

The attachment assembly in its assembled configuration is configurable in a locked state or in an unlocked state. When in the unlocked state, the first part and the second part are retained in a retained state by frictional retention forces, and the first and second parts can be separated from the retained state by applying a withdrawal force to move the first part in a withdrawal direction relative to the second part to overcome the frictional retention force. When in the locked state, the first part and the second part are locked in the retained state, the first part is at a retention position relative to the second part, and movement of the first part in the withdrawal direction relative to the second part is impeded by a stop mechanism.

The first part and the second part may be locked in the retained state by a stop mechanism. The stop mechanism may be configured to always operate in an actuation state, and will remain in the actuation state unless and until a de-actuation force is applied to switch the stop mechanism to change into a de-actuated state. When the stop mechanism is de-actuated, the attachment assembly is in the unlocked state, the stop mechanism no longer impedes movement of the first part in the withdrawal direction, and the first part can be detached from the second part by moving along the withdrawal direction relative to the second part after having overcome the frictional retention forces.

The first part and the second part are at a predetermined relative position and the first part is at a retention position relative to the second part when the attachment assembly is in its assembled configuration. When in the assembled configuration, the attachment assembly is in a stable condition, and the frictional retention forces alone are sufficient to maintain the first part in the retention position even in the unlocked state, so that the first part would not separate from the second part due to influence of gravity when the withdrawal direction is same as the direction of gravity force.

When the first part is in the retention position, the stop mechanism is operable to lock the attachment assembly so that the first part and the second part cannot be detached by moving the first part in the withdrawal direction without causing damage to the first part or the second part.

When the first part is move out of the retention position while still in abutment with the second part, the first part and the second part can be detached by moving the first part in the withdrawal direction after having overcome the frictional retention forces and without causing damage to the first part or the second part.

To disassemble the attachment assembly, the stop mechanism is de-actuated to change the attachment assembly from the locked state to an unlocked state. After the assembly has been switched into the unlocked state, the first part is moved in a withdrawal direction relative to the second part until the first part and the second part are out of retention engagement, and further movement of the first part in the withdrawal direction will result in total detachment of the first part from the second part.

If the stop mechanism is de-actuated while in the assembled configuration and the first part is not moved out of the retention position, the assembly will return to the locked state as soon as the de-actuation force disappears. The return to the locked state is by automatic internal operation of the stop mechanism and does not require application of actuation force from outside of the assembly.

To form the assembly, the first part is moved towards the second part in a first direction until the first part has reached the retention portion. The first direction is an attachment direction which is defined by a first axis X-X′ and a first plane. The first plane contains the first axis and is defined by the first axis in cooperation with a second axis Y-Y′. The second axis is a transverse axis which is orthogonal to the first axis and which defines a second direction. On arriving at the retention position in the attachment direction which is opposite to the withdrawal direction, the assembly automatically enters into the locked state due to automatic operation of the stop mechanism. When in the locked state, the first part and the second part are retained by frictional retention forces, and the first part is impeded to move away from the second part along the withdrawal direction due to the stop mechanism. The attachment direction defines a first direction which is along the first axis and towards the second part.

The first part comprises a main housing, an engagement portion and a stop portion on the main housing. The second part comprises a main housing, an engagement portion and a stop portion on the main housing. The main housings of the first and second parts are compatible corresponding housings which are complementarily matched and are in coupled engagement when in the assembled state.

The engagement portion of the first part and the engagement portion of the second part are corresponding engagement portions which are configured to facilitate coupled engagement between the first part and the second part when the assembly is in its assembled configuration. The engagement portion of the first part comprises a plurality of engagement parts and the engagement portion of the second part comprises a corresponding plurality of corresponding engagement parts.

An engagement part of the first part and a corresponding engagement part of the second part are compatible corresponding engagement parts of an engagement device. An engagement device herein comprises an engagement part on the first part and a corresponding engagement part on the second part. The engagement part and the corresponding engagement part are complementary and matched and are to enter into coupled engagement when the first part is brought into the retention position.

The coupled engagement may comprise frictional engagement. To facilitate frictional engagement between the first part and the second part, the corresponding engagement portions may be configured to cooperate to form a frictional catch system comprising a plurality of frictional joints. The frictional joints may be distributed along a peripheral portion of the assembly to provide a more evenly distributed frictional retention force. A frictional joint is formed by an engagement part and a corresponding engagement part. The frictional joint is formed when an engagement part and a corresponding engagement part enter into coupled engagement.

The stop portion of the first part and the stop portion of the second part are corresponding stop portions which are to cooperate to form a stop means. The stop means comprises the stop mechanism and optionally an auxiliary stop device. The auxiliary stop device may be configured to impede movement in a direction orthogonal to the first plane.

The main housing of the first part is a hollow housing which is configured as a container for receiving components, circuitries and/or mechanisms. The hollow housing comprises a first housing portion, a second housing portion and a peripheral portion interconnecting the first housing portion and the second housing portion. The first housing portion comprises a first panel, the second housing portion comprises a second panel and the peripheral portion comprises a peripheral panel, and the panels cooperate to define an internal compartment for receiving circuitries. The circuitries may comprise electrical circuitries and/or electronic circuitries. The components may comprise electrical components, electronic components and/or mechanism components. The mechanisms may comprise the circuitries and components.

The stop portion of the first part comprise a stop mechanism which is mounted inside the main housing and which is operable in an actuation state which is an actuated state or a de-actuation state which is a de-actuated state. When the stop mechanism is in the actuation state, relative movement between the first part and the second part in the withdrawal direction is impeded or resisted by the actuated stop mechanism. When the stop mechanism is in the de-actuation state, relative movement between the first part and the second part in the withdrawal direction is not impeded or resisted by the de-actuated stop mechanism, and the first part can be removed in the withdrawal direction after overcoming the retention force of the interference fit engagement.

The stop mechanism comprises a stop member which is movable in a direction that is orthogonal to the first plane. When the stop mechanism is in the actuation state, the stop member is in an extended state. When in the extended state, the stop member protrudes through the second housing portion of the first part and extends into the second part to impede movement of the first part in the withdrawal direction relative to the second part. When the stop mechanism is in the de-actuation state, the stop member is in a retracted state. When in the retracted state, the stop member does not interfere with movement of the first part in the withdrawal direction relative to the second part.

The stop mechanism is installed inside the main housing of the first part and is accessible through an access aperture devised on the peripheral portion of the main housing. To de-actuate the stop mechanism, an operator is to apply a de-actuation force from outside of the main housing and though the access aperture. To actuate the stop mechanism, the operator does not need to apply any external force, and the stop mechanism will return to its actuation state automatically by operation of an internal actuation force which is stored on the stop mechanism.

The main housing of the second part is configured as a receptacle for holding the first part. The receptacle comprises a first portion which is a base portion and a second portion which is a peripheral portion. The peripheral portion defines a boundary and an entry aperture through which the first part is to move into the retention position. The boundary includes a first portion which is an end portion defining an axial limit of the receptacle and a second portion which is a lateral portion defining the lateral limits of the receptacle. An entry aperture is defined on the peripheral portion so that the first part can move into the retention position after passing through the entry aperture.

The attachment assembly is configured such that the access aperture on the peripheral portion of the first part is accessible via the entry aperture defined on the peripheral portion of the second part. So that the first part will move towards the second part along the first axis and the first plane to enter into coupled engagement with the second part, corresponding guide means are disposed on the first part and the second part. As the first part is to enter into the retention position after passing through the entry aperture, the attachment direction is also conveniently referred to as an insertion direction and the first axis is also referred to as an insertion axis.

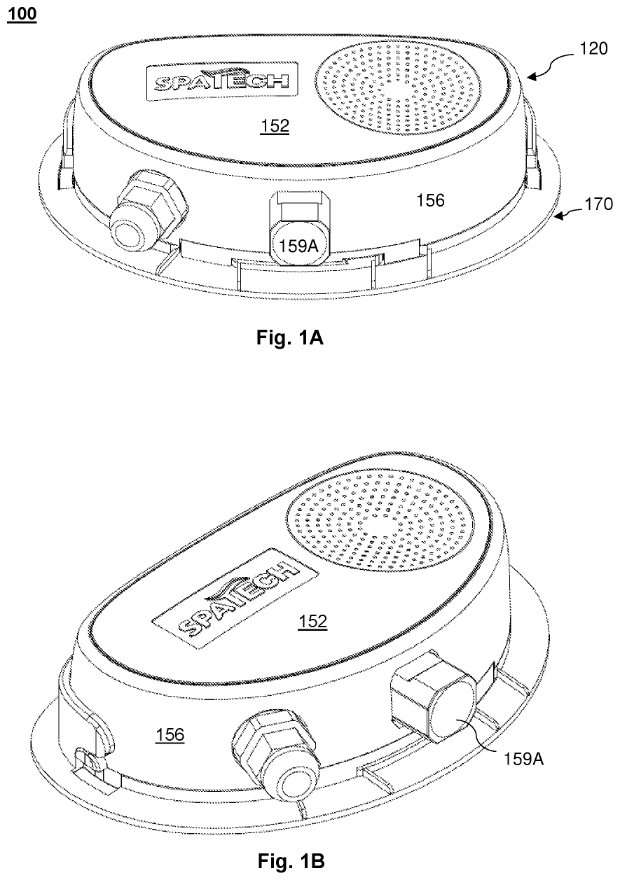

Referring to FIGS. 1A, 1B and 1C, an apparatus 100 as an example attachment assembly comprises a first part 120 and a second part 170.

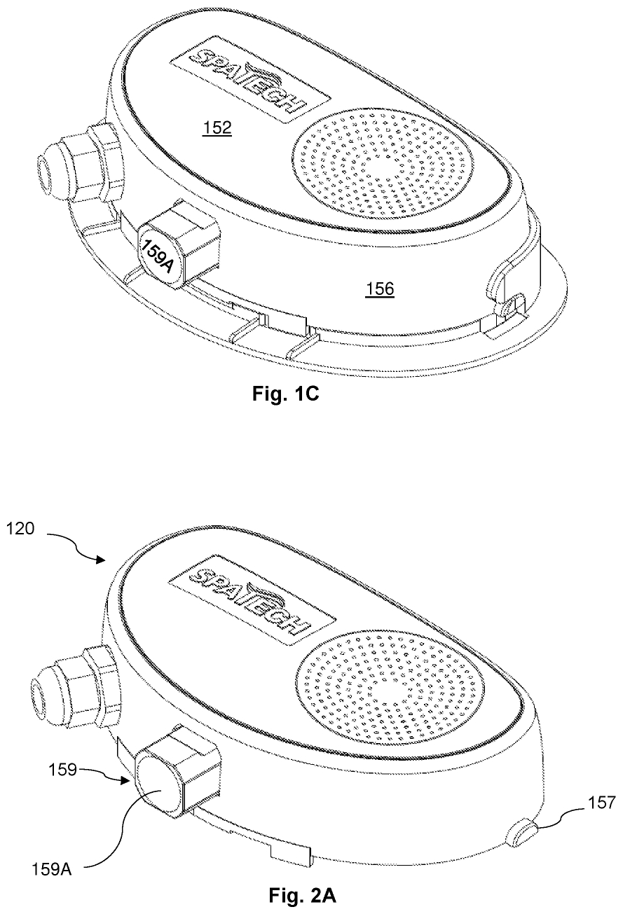

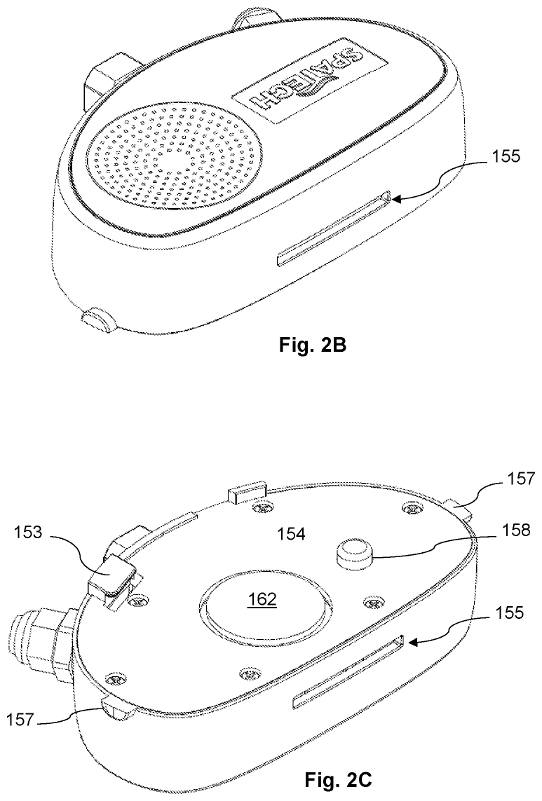

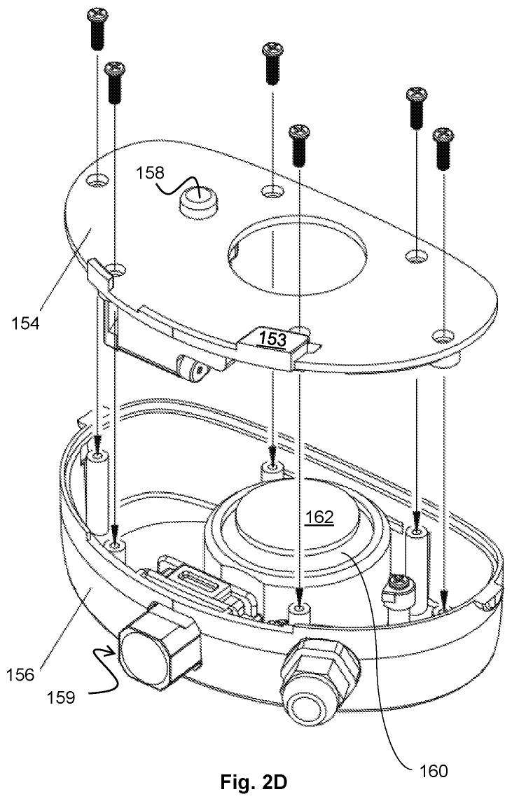

Referring to FIGS. 2A, 2B, 2C and 2D, the first part 120 is configured as a cartridge and comprises a main housing which is configured as a cartridge housing. The main housing comprises a first portion including a first panel 152, a second housing portion including a second panel 154, and a third portion which is a peripheral portion including a peripheral wall 156. The first panel 152, the second panel 154 and the peripheral wall 156 cooperate to define an internal compartment inside which components, circuitries and/or mechanisms are disposed.

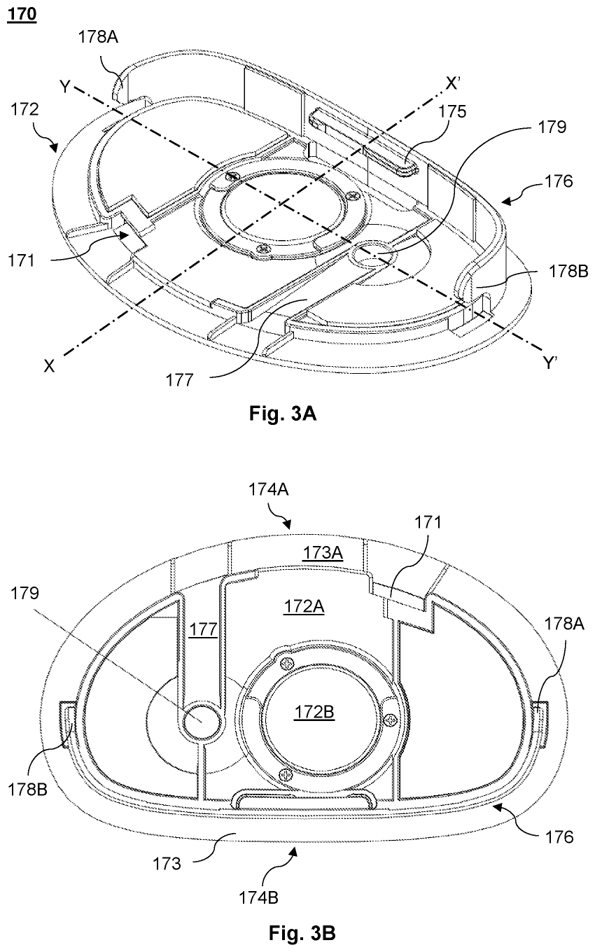

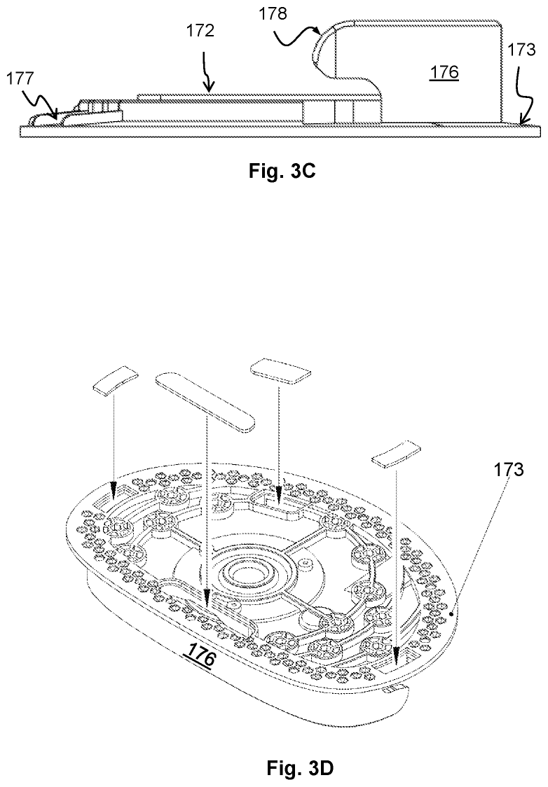

Referring to FIGS. 3A, 3B, 3C and 3D, the second part 170 comprises a first portion which is a base portion 172 and a second portion which is a peripheral portion comprising a peripheral wall 176.

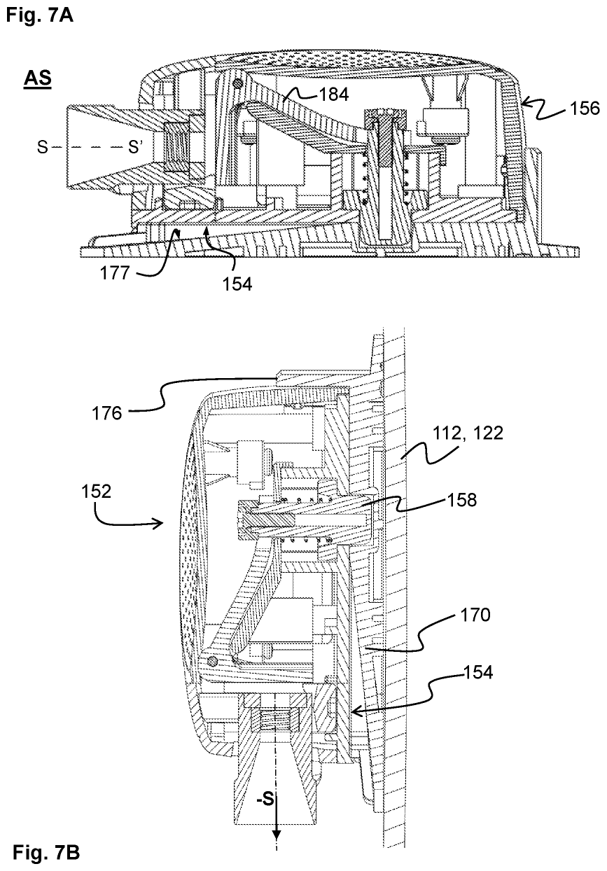

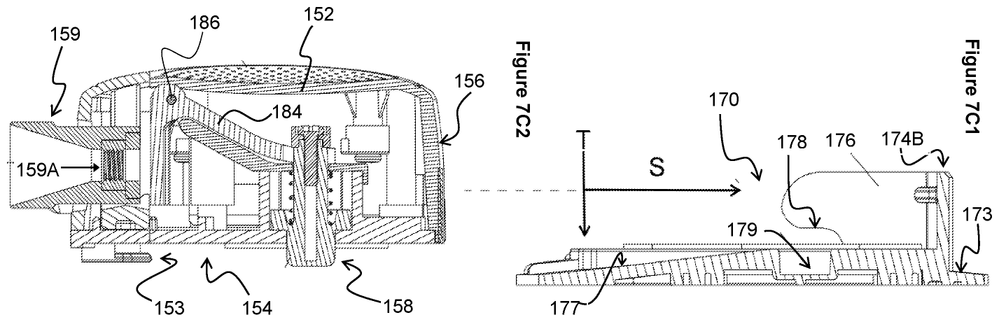

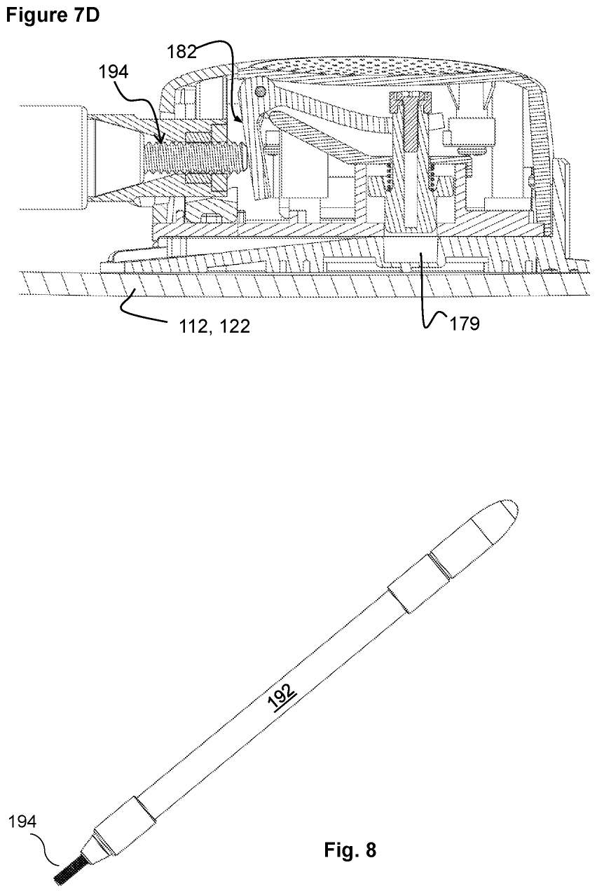

Referring to FIGS. 7A, 7B and 7C (including 7C1 and 7C2) and 7D, a stop member 158 is disposed inside the main housing of the first part 120. The stop member 158 projects through the second housing portion and extends into the second part 170. An axial end of the stop member is received inside a receptacle 179 on the second part 170 and the stop member is contained by the receptacle so that movement of the stop member in the withdrawal relative to the second part is impeded due to confinement of the stop member by the receptacle. The stop member 158 is part of a stop mechanism which is operable in an actuation state or a de-actuated state. When the stop mechanism is in the actuation state, movement of the stop member at least in the withdrawal direction is impeded by the second part. When the stop mechanism is in the de-actuation state, movement of the stop member in the withdrawal direction is not impeded by the second part. The stop mechanism is configured so that its neutral state is the actuation state. The stop mechanism is in a neutral state when no external force is applied to intervene or change the mechanical state the stop mechanism. The external force may be applied in the form of a de-actuation force which is a type of intervention force.

The stop member has a main body which extends along a body axis between a first axial end and a second end. The first axial end is an enlarged head which is distal from the second housing portion. The second axial end is a stud head which is configured to impede movement of the first part relative to the second part when the assembly is in the locked configuration.

The stop member has an axial end which is movable into and out of the second part. When in the actuation state, the axial end is inside the second part and movement of the stop member at least in the withdrawal direction is impeded by the second part or a confinement device formed thereon. When in the de-actuation state, the axial end is outside of the confinement device and movement of the stop member in the withdrawal direction is not impeded by the second part or the confinement device. When the stop mechanism is in the neutral state, which is also a natural state, the axial extent of the stop member outside the first part is at its maximum. The stop member in the actuation state is in an impeding state. The stop member in the de-actuation state is in a clearance state.

The stop member and the receptacle are corresponding stop parts which cooperate to form a stop device. The receptacle is configured to confine the stop member when the stop mechanism is in the actuation state and not to confine the stop member when the stop mechanism in the de-actuation state.

The example receptacle is optionally configured as a bore having a bore wall, and relative movement of the stop member 158 along the first plane, including along the withdrawal direction and the transverse direction, is impeded by the bore wall when in the locked state.

The example stop member is configured as a stud having a stud body which extends along a stud axis between a first axial end and a second axial end. A spring 188, for example a coil spring, is devised to provide an urging force to urge the stop member to attain a maximum axial protrusion from the first part when the stop mechanism is in the neutral state.

A de-actuation mechanism which is operable in an actuation state or a non-actuation state is provided to change the stop mechanism from the actuated state to the de-actuated state. To change the operation state of the stop mechanism from its neutral state, the de-actuation mechanism is to operate to act against the urging force which urges the stop member to project towards the second part. To change the stop mechanism from the actuated state to the de-actuated state, the de-actuation mechanism is required to operate in the actuation state to move the stop member out of confinement of the confinement device and the confinement of the second part. When the de-actuation mechanism is in the non-actuation state, the stop member is movable relative to the de-actuation mechanism between the actuated state and the de-actuated state.

The example de-actuation mechanism comprises a pivot arm which is disposed between the stop member and the access aperture. The pivot arm comprises a first arm portion 182, a second arm portion 184 and a hinge 186 which is intermediate the first portion and the second portion. The first arm portion and the second arm portion are rigidly joined at the hinge, and may be integrally formed as a single arm piece. The hinge 186 has a hinge axis which is parallel to the transverse axis and the arm piece is pivotally movable about the hinge axis between a first angular position which is a non-actuation position and a second angular position which is an actuation position. The de-actuation mechanism is configured such that when the arm piece is at the first angular position, the stop member is in the actuated state or the impeding state, and when the arm piece is at the second angular position, the stop member is in the de-actuated or the clearance state and is clear of obstacles which impede movement in the withdrawal direction.

The first arm portion 182 has a hinged end and a free end, and extends from the hinged end to the free end at a small angle with respect to a third axis. The third axis is orthogonal to the first plane and defines a third direction. The small angle, which is an inclination angle of the first arm portion 182 with respect to the third axis, may be within ±10°. The hinged end of the first arm portion 182 is distal from the second housing portion and the free end is proximal to and clear of the second housing portion.

The second arm portion 184 has a hinged end and a load end, and extends from the hinged end to the load end at a small angle with respect to the insertion direction. The small angle, which is a depression angle with respect to the insertion direction, may be 30° or smaller, for example, between 15° and 30°.

The second arm portion 184 is at an acute angle with respect to the first arm portion 182, and the acute angle, which is an included angle facing the second housing portion, may be 75° or smaller, for example, between 45° and 75°.

The first arm portion 182 is juxtaposed with the access aperture and can be accessed from outside of the first part. The load end is connected to the stop member 158 such that when an external intervention force is applied in a direction parallel to the insertion direction and acts on the first arm portion 182 and about the hinge, the arm piece will be rotated about the hinge axis and move towards the second angular position. Rotation of the arm piece towards the second angular position operates to retract the stop member from its maximally extended state towards a clearance state at which movement of the first part relative to the second part is not or no longer obstructed by the stop mechanism. When the externally applied intervention force is removed, the stop member is returned to its actuated state by the urging force and the arm piece is automatically returned to the first angular position to lock the assembly in the locked state.

The angular difference between the first and second angular positions may be selected according to the clearance stroke length of the stop member, which is a measure of the difference in protrusion length between the maximally extended state and the clearance state.

The angular difference between the first and second angular positions may be selected according to the mechanical advantage for moving the stop member from the actuation state to the de-actuation state. The mechanical advantage may be smaller or larger than 1.

The de-actuation mechanism and the stop mechanism are movably connected. The stop mechanism can operate either in the actuated state or in the de-actuated state when the de-actuation mechanism is in the non-actuation state. When the de-actuation mechanism is in the actuation state, the stop mechanism is moved to the de-actuation state and is no longer movable relative to the de-actuation mechanism.

The load end of the second arm portion 184 is movably connected to the stop member 158. More specifically, the load end of the second arm portion 184 is movably attached to the main body between the enlarged head and the stud head.

Referring to FIGS. 7A and 7C1, the de-actuation mechanism is in its non-actuation state and the stop mechanism in its actuated state. When in this configuration, the stop member 158 is in the impeding state and the de-actuation mechanism is in the non-actuation state due to an urging force, for example, the urging of a spring 188. When in this configuration, the pivot arm is at the first angular position and the stop member 158 can be moved to the clearance by application of an external force on the stop member 158 in a direction to retract.

In this example, the de-actuation mechanism has a mechanical advantage of higher than 1, since the second arm portion 184 is longer than the effective length of the first arm portion 182. The effective length of the first arm portion 182 is measured between the hinge axis and an access axis S-S′, since the de-actuation force is applied on the first arm portion 182 most probably along the access axis. The access axis is parallel to the insertion axis, and intermediate the insertion axis and the hinge.

In this example, the clearance stroke length is 5 mm, but may be set to any value, for example larger than 3 mm or smaller than 15 mm, depending on applications and safety margin required. The angular difference is about 5° in this example, but may be set to be between 5° and 15°, depending on the clearance stroke length and mechanism advantage.

In this example, the arm piece is to rotate counter-clockwise from the first angular position to the second angular position, and clockwise from the second angular position to the first angular position. The rotation direction may be opposite if the relative position between the access aperture and the stop member are changed.

To facilitate application of de-actuation force, a coupling port is provided on the first part. The example coupling port 159 is formed on the peripheral portion of the first part and defines an access aperture 159A, through which the de-actuation force can be applied. The coupling port may comprise a tubular portion, for example, a tubular portion having an internal thread so that a de-actuation tool may be attached to the coupling port 159 and therefore the first part by threaded coupling.

An example de-actuation tool comprises an elongate main body and a head portion which protrudes axially from the elongate main body. The tool may be configured to make coupled engagement with the first part so that when the tool is in coupled engagement with the first part, for example, with the coupling port, the tool is secured with the first part and the de-actuation mechanism is driven into the de-actuation state by the head portion.

An example de-actuation tool comprises a main body and a threaded head which is compatible with the threads of the coupling port. The main body 192 is elongate and the threaded head 194 protrudes axially from the elongate main body which defines a handle portion 192, as shown in FIG. 8.

To detach the first part from the second part while the assembly is in the locked state, the head 194 of the de-actuation tool is inserted into the coupling port 159 to make coupled engagement with the first part. To make coupled engagement with the first part, an operator is to rotate the tool so that the external threads on the tool make threaded engagement with the internal threads on the coupling port 159. After the threaded engagement has been made, the tool is rotated further to bring the head portion towards the de-actuation mechanism. The tool may be configured such that when threaded advancement towards the de-actuation mechanism in the access direction S is at an end, the head portion is in abutment with the de-actuation mechanism and the stop member is at the clearance state due to the abutment.

Referring to FIG. 7D, the head 194 is at the end of threaded advancement towards the de-actuation mechanism, the axial end of the head 194 is in abutment with the first arm portion 182, the stop member is retracted to the clearance state, and the stop mechanism is in the de-actuation state.

When the stop member is in the clearance state, the first part can be detached from the second part by moving the tool in a retrieval direction −S, which is opposite to the access direction S. To totally detach the first part from the second part, an operator would need to overcome the frictional retention forces which retain the first part on the second part.

Since the tools is secured to the first part while the stop mechanism is de-actuated, the first part can be detached from the second part using the same tool, that is, by moving the tool in the withdrawal direction.

The tool can be used to attach the first part to the second part by a similar set of operations. To attach the first part to the second part, the tool is to enter into coupled engagement with the first part while the first part and the second part are separated. After the tool and the first part are in coupled engagement, the first part is moved by the tool in the first direction towards the second part until the first part is in the retention position and is retained by frictional engagement forces in the assembled configuration. When in the assembled configuration, the coupled engagement between the tool and the first part is released and the stop mechanism is returned to the actuation state and the first part and the second part are locked in the locked state.

The coupled engagement between the first part and the tool may be by means other than threaded engagement, for example, by bayonet-type engagement without loss of generality.

A tool for attaching the first part to the second part may have a different head configuration. For example, the head portion of the tool may have a shorter length so that the head portion does not drive the de-actuation mechanism into the de-actuation state at the end of its course of advancement into the second part when the tool is securely coupled to the second part. When this attachment tool is used, the stop mechanism will remain in the actuation state during the course and at the end of advancement.

When this attachment tool is used, the stop mechanism will automatically enter into the locked state once the first part enters the retention position.

The first part and the second part are configured such that when the first part moves in the first direction relative to the second part, the first part and the second part are to automatically enter into the locked state on arriving at the retention position, except when the stop mechanism is de-actuated.

A guide track 177 is optionally provided on the base portion, as shown in FIGS. 3A, 3B and 3C. The guide track extends between a first end and a second end in a direction which is parallel to the insertion direction. The guide track is configured to guide the stop member to move along a direction which is parallel to the first direction when the first part is advancing in the first direction towards the retention position. The first end is an entry end and the second end is an exit end of the guide track when the first part is to move towards the retention position. The second end of the guide track is an abrupt end which is delimited by an impeding wall. The impeding wall is configured to obstruct movement of the stop member in the withdrawal direction once the stop member moves past the second end when the first part is advancing towards the retention position.

As shown in FIG. 3B, the receptacle 179 abuts the guide track and the stop member is to enter the receptacle once it advances past the guide track.

The guide track may be configured such that when the first part is on the first plane and begins to encounter the second part, the stop member will encounter the first end of the guide track and its protruding stud end is on the guide track and in abutment therewith. When the first part moves towards the retention position, the stop member will interact with the guide track surface and is pushed towards the clearance state.

The guide track is optionally an inclined track so that the stop member is to progress towards the clearance state on advancing along the guide track, and flip to the impeding state one it passes the guide track.

The engagement portion of the first part comprises a plurality of engagement parts 153, 157, which is configured to enter into frictional engagement with corresponding engagement parts on the second part. The engagement parts are distributed along the forward portion of the peripheral portion of the main housing, which is the portion on which the access aperture is defined. The friction engagement facilitates detachable attachment between the first part and the second part, and facilitates detachment of the first and second parts upon application of a detachment force in the withdrawal direction to overcome the frictional engagement force.

The stop portion of the first part comprises at least a stop part 155. The stop part is configured to engage with a corresponding stop part 175 on the second part to impede movement of the first part in an orthogonal direction away from the first plane.

The second part 170 comprises a base portion including a seat portion 172 and a peripheral portion including a peripheral wall which is upwardly dependent from the base portion. A plurality of engagement parts 171, 178A, 178B is formed on the base portion and at least one stop part 175 is formed on the peripheral wall.

The seat portion 172 comprises a forward end 174A, a rearward end 174B and lateral sides extending between the forward end 174A and the rearward end 174B. The seat portion 172 comprises an upper surface defining a seat surface and a lower surface for attaching to a support surface such as an interior surface of the bathtub. The forward end 174A, the rearward end 174B and the seat surface 172A are sequentially disposed along the insertion direction S, which is defined by an S-axis.

The peripheral wall 176 extends upwardly from the seat surface for a height H which is comparable to the height of the main housing of the first part, which is configured as a cartridge housing. The height of the cartridge housing is measured between the first surface and the second surface in a second direction T. The T-direction is an axial direction which is defined by a T-axis which is orthogonal to the S-axis.

The peripheral wall 176 extends to delineate the rearward end 174B of the seat portion 172 and has peripheral ends which are forward of the rearward end 174B. The peripheral ends are lateral ends which extend forwardly from the rearward portion of the peripheral wall 176 which delineate the rearward end 174B of the seat portion. The lateral ends of the peripheral wall 176 are forward free ends which are most distal or most forward from the rearward end 174B of the seat portion 172.

Each forward free end of the peripheral wall 176 is an overhanging forward portion which overhangs the base portion of the second part 170, which is configured as cartridge bracket. The overhanging forward portion cooperates with the base portion to define an elongate slot having a slot entry at its forward end. The overhanging forward portions are configured to cooperate with the base portion to form a pair of engagement parts. The engagement parts are configured as a pair of lateral clamps 178A, 178B. Each lateral clamp is configured to exert a clamping force in a direction parallel to the T-direction. The lateral clamps are configured to enter into frictional engagement with the part of engagement parts 157 on the first part. The peripheral wall 176, comprising the peripheral ends, forms a brace which surrounds a rearward portion of the seat surface 172A.

The peripheral wall 176 has a depth which may be between ⅓ or ½ of the depth of the cartridge bracket 170. The depth of the cartridge bracket 170 is measured between the forward end of the peripheral wall 176 and the rearward end of the seat portion 172. Both the depth of the cartridge bracket 170 and the depth of the peripheral wall 176 are measured in the S-direction.

The cartridge bracket 170 comprises a web portion 173 which extends outwardly from the seat portion 172 with respect to the T-axis. The web portion includes a forward web portion 173A which is forward of the seat portion 172. The web portion has a lower surface which may be flush with the lower surface of the seat portion 172 and an upper surface which is below the seat surface at the forward end 174A. The web portion may extend to surround the seat portion 172. In some embodiments such as the present, a step is formed at the junction between the seat portion and the forward portion, and the seat surface is elevated above the forward portion by a height equal to the height of the step. The step may have a height of 1 mm or more, for example, 1 mm, 1.5 mm, 2 mm, 2.5 mm, 3 mm, 4 mm, 5 mm, etc.

Referring to FIGS. 3A to 3C, the overhanging forward portions on opposite peripheral ends of the peripheral wall cooperate with the seat surface 172A to define a pair of lateral clamps 178A, 178B. Each lateral clamp 178A, 178B comprises a slot, for example, an elongate slot, which is defined by cooperation of the overhanging forward portion and the seat surface. The elongate slot has a slot entrance at its forward end and is configured to receive a portion of the cartridge housing so that an interference engagement is formed between the lateral clamps 178A, 178B and the portions of the cartridge housing received inside the lateral clamps 178A, 178B.

The portion of the cartridge housing which is configured to be received inside lateral clamp 178A, 178B when in the engagement position may be a protruding portion 157 which is an engagement part that projects transversely outwards from the peripheral wall 156 of the cartridge housing. The slot may be a tapering slot having a clearance in the upward direction which gradually reduces on progressing towards the rearward end. With the tapering slot, the protruding portion on the peripheral wall 156 of the cartridge housing and the overhanging portion will enter into wedged engagement on progressing into the engagement position. In some embodiments, the protruding portion may be configured as a wedging portion having a forward end which is higher than its rearward end so that the protruding portion gradually enters into wedging engagement with the lateral clamp 178A, 178B, which defines an overhanging clamp portion. In some embodiments, the wedging engagement may be formed partly by an inclined seat surface which cooperate with the overhanging clamp portion to define a tapered engagement slot.

The overhanging forward-end portions of the peripheral wall of the cartridge bracket 170 may be configured as a brace which is to exert a transversal bracing force to brace the cartridge housing. To facilitate formation of a brace, the transversal separation distance between the two overhanging lateral forward-end portions on opposite peripheral ends of the peripheral wall of the cartridge housing is smaller, for example, slightly smaller, that the width of the cartridge housing being braced. The transversal separation distance herein is measured in a transversal direction which is orthogonal to both the S-direction, which is the direction of insertion, and the T-direction, which is an upward direction with respect to the base portion. The S-direction is defined by the S-axis which may be an axis of lateral symmetry of the cartridge bracket.

Each overhanging forward-end portion of the peripheral wall has an inner surface which is parallel to the T-axis, and the inner surfaces of the two overhanging forward-end portions are oppositely facing and aligned on a transversal axis which extends in the transverse direction. The transversal axis is orthogonal to both the S-axis and the T-axis, and parallel herein includes substantially parallel, for example, with a ±15 degrees deviation. In some embodiments such as the present, the peripheral wall 176 is symmetrically disposed about the centre axes S and T.

The cartridge bracket 170 may be configured such that, when the first part is in the retention position, the inner surfaces of the overhanging forward-end portions are in compressive engagement with the peripheral wall of the cartridge housing, and the resilience of the overhanging forward-end portions is to exert a transversely inward bracing force against the peripheral wall of the cartridge housing. The transversely inward bracing force is exerted in a transversely inward direction which is towards the S-axes.

Therefore, the peripheral wall, or more specifically the peripheral end portions of the peripheral wall, may be configured as a bracing device which is to exert a transversely inward bracing force, and/or as a clamping device which is configured to exert a clamping force in a direction parallel to the upward axis T without loss of generality. In other word, the engagement means formed by the peripheral ends of the peripheral wall may be configured as an engagement means for exerting an inward transversal engagement force and/or an upward engagement force.

The cartridge housing may include a clamping arrangement which is configured to engage with cartridge bracket 170. An example clamping arrangement comprises a clamping portion 153 which is an engagement part formed underneath the second surface 154. The clamping portion 153 is formed on the rearward end of the cartridge housing and has its forward opened to form an entrance, as shown in FIGS. 2C, 2D and 7C2. The clamping portion 153 is configured to make clamping engagement with the seat portion when in the engagement position. To facilitate clamping engagement between the clamping portion 153 and the seat portion, a clamp receptacle 171 is formed on a forward end portion of the seat portion underneath the seat surface. When in the engagement position, the clamp portion 153 is received inside the clamp receptacle 171, and the second surface 154 and the clamp portion 153 cooperate to exert a clamping force in the T-direction on the seat portion to facilitate frictional engagement.

A stop part 175 is formed on the peripheral wall. The stop part 175 is a protrusion which extends forward of the peripheral wall for making stop engagement with a stop part 155 on the main housing. The stop part 155 on the main housing is a slot which is to receive the stop part 175 in a closely fitted manner to form a stop device at the rear end of the assembly. This stop device operates to impede movement of the first part away from the second part in the minus T-direction.

It is noted that the engagement devices formed by the engagement parts 171, 178A, 178B are also stop devices which operate to compressively lock the first and second part in the T-direction so that the first part cannot move away from the second part in the minus T-direction unless the first part is moved out of the retention position.

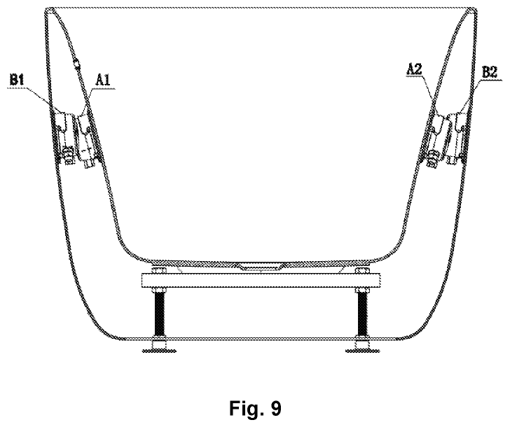

The assembly may be configured as an audio cartridge. Referring to FIG. 9, a plurality of audio cartridge A1, A2, B1, B2 is disposed on inside surfaces of a bath tub. The audio cartridge A1, A2, B1, B2 comprises an audio transducer 160 and circuitries for operating the audio transducer 160.

The audio transducer 160 comprises a front surface 162 and a back surface. The audio transducer 160 is mounted on the cartridge housing such that the front surface is proximal the front surface of the cartridge housing and the back surface is inside the internal compartment of the audio cartridge A1, A2, B1, B2. The front surface 162 of the audio transducer is a sound propagating surface which is to mechanically vibrate to propagate audible signals. The audio transducer is configured to receive electrical audio signals from the signal source and to convert the received electrical audio signals into mechanical vibrations for onward propagation as audible signals.

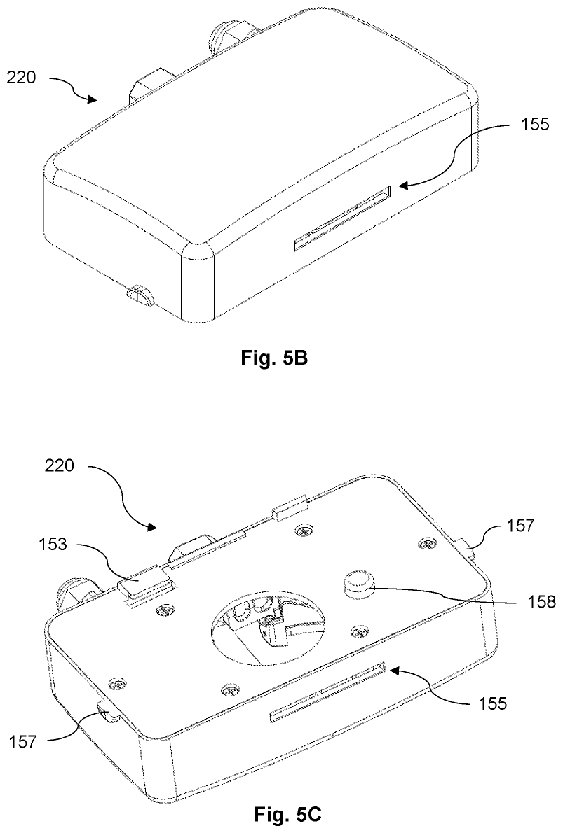

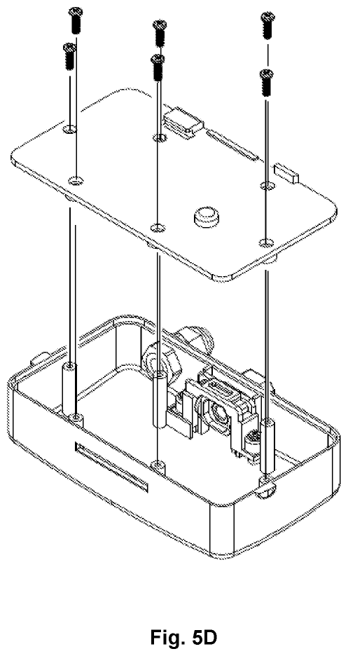

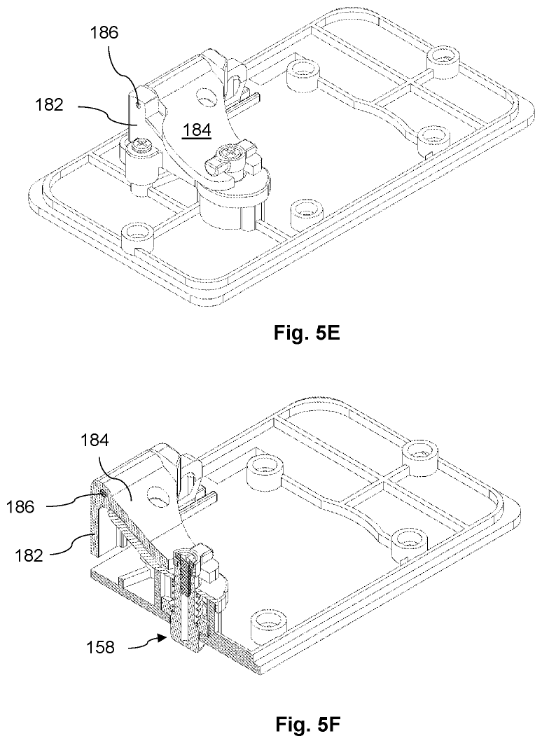

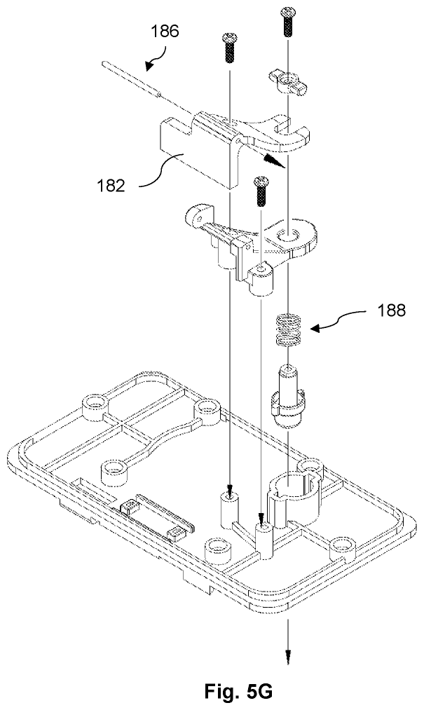

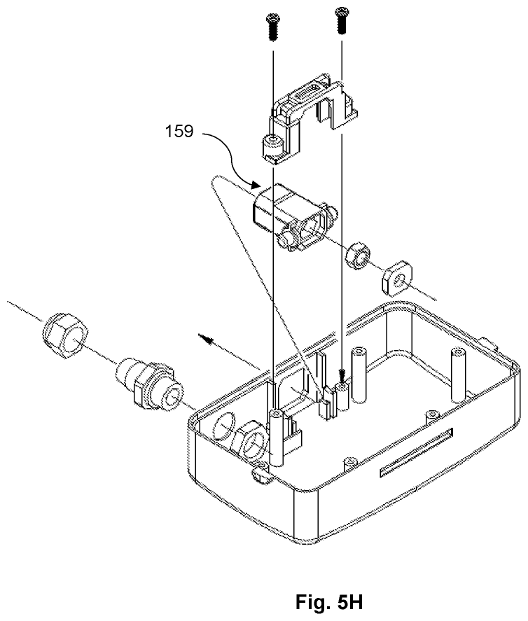

The audio cartridge A1, A2, B1, B2 is configured for attachment to the bathtub, for example, by means of a cartridge receptacle, such that mechanical vibration generated by the audio transducer can propagate through physical contact with the first container, the second container and/or the bridging portion. An example cartridge receptacle as shown in FIGS. 5A and 5B is configured as a cartridge bracket 170.

An audio cartridge assembly AS comprising an audio cartridge and a cartridge receptacle includes a cooperative retention system which is configured to facilitate retention of the audio cartridge on the cartridge receptacle, as shown in FIG. 7A. The cooperative retention system comprises a retention mechanism on the audio cartridge and a counterpart retention mechanism on the cartridge receptacle. The retention mechanism on the cartridge housing may comprise an engagement means and/or a locking means. The counterpart retention mechanism on the cartridge receptacle may comprise a counterpart engagement means and/or a counterpart locking means. The engagement means and the counterpart engagement means cooperate to form an engagement system which is configured to keep the audio cartridge and the cartridge receptacle engaged, for together by pressure engagement, such as friction engagement or snap engagement. The locking means and the counterpart locking means cooperate to form a locking system which is configured to lock the audio cartridge and the cartridge receptacle together in a locked relationship when a locking position.

An audio cartridge assembly AS attached on a support surface 112, 122 is shown in FIG. 7D. The support surface may be internal surfaces of a bath tub, as shown in FIG. 9. The audio cartridge assembly AS is configured such that the audio cartridge is detachable from the cartridge receptacle 170 by moving downwardly relative to the peripheral wall 112, 122 towards the support surface SS, that is, in a negative S direction.

The cartridge receptacle 170 may be pre-fitted or post-fitted to the support surface 112, 122, which may be the internal peripheral walls of a bath-tub, for example, by gluing or other mean of fastening. A plurality of cartridge receptacles may be pre-fitted at selected locations along the inter-container space for selected attachment of audio cartridges as and when a user so desires. The cartridge receptacles are preferably configured so that an audio cartridge is to enter into snap engagement with a corresponding cartridge receptacle when moving upwards towards the cartridge receptacle.

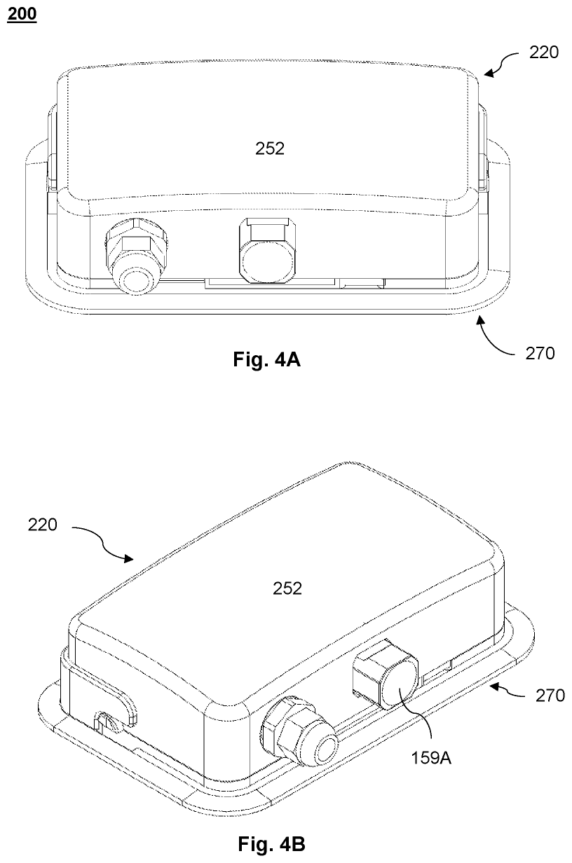

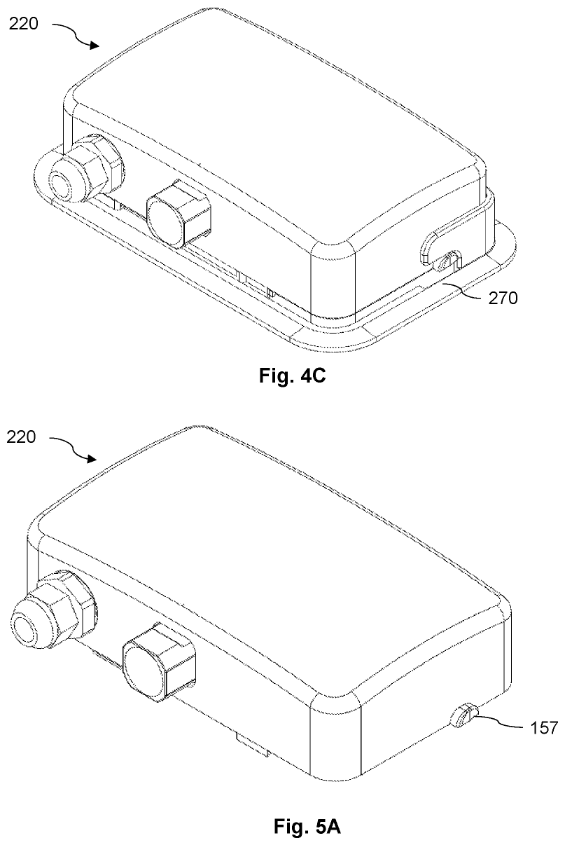

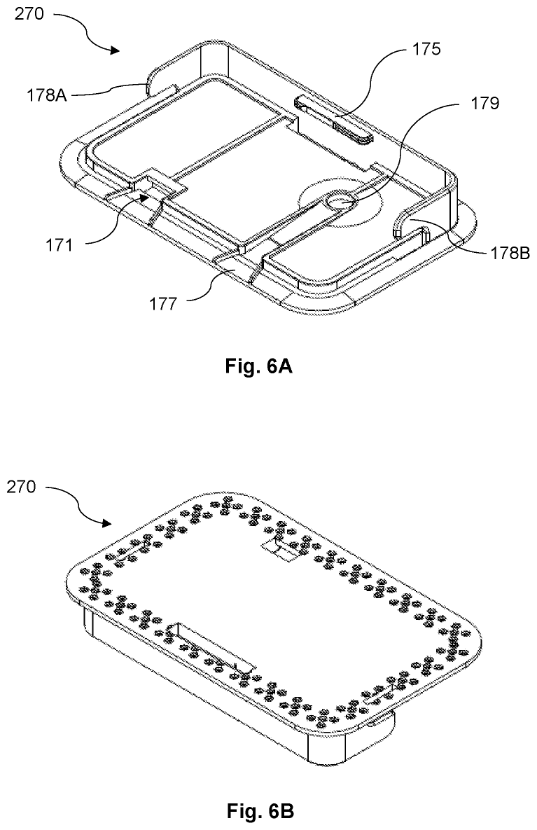

An example assembly 200 shown in FIGS. 4A to 4C, 5A to 5H, 6A and 6B comprises a first part 220 and a second part 270. The first part 220 has a main housing which is different to that of the apparatus 120 of FIG. 1A, and the second part 270 is configured for detachable reception of the first part and has corresponding shape and dimensions. The example assembly 200 comprises the same stop mechanism and the same de-actuation mechanism and the same numerals are used to indicate the same part for succinctness,

A method of removing an apparatus from a narrow space is disclosed. The apparatus is mounted on a receptacle inside the narrow space, the narrow space being defined between a first wall and a second wall and having a transversal clearance; wherein the apparatus comprises a cartridge according to any preceding claims and having an engagement port; and wherein the method comprises engaging the engagement port of the apparatus with the tool, whereby latching between the apparatus and the receptacle is released, and moving the apparatus out of the receptacle and then out of the narrow space.

The method may comprise: advancing the tool towards the apparatus, connecting the tool and the apparatus so that the tool is retained by the access portion, and advancing the tool until latching between the apparatus and the receptacle is released.

A method of mounting an apparatus inside a narrow space which is defined between a first wall and a second wall and having a transversal clearance, wherein the apparatus comprises a cartridge. The method comprises:
a. connecting the apparatus and first threaded end of the tool;
b. Moving the apparatus into the narrow space and towards a receptacle until the cartridge is retained on the receptacle, the receptacle being inside the narrow space;
c. Detaching the tool from the apparatus after the apparatus is retained by the receptacle, and
d. moving the tool out of the narrow space.

The method further comprises attaching the receptacle to the first wall or the second wall by adhesives.

While the present disclosure is made with reference to examples, the examples are not intended to be limited.

1. An attachment apparatus comprising a main housing and an attachment arrangement for securing the main housing to a surface-mountable receptacle,
wherein the main housing is configured to move along a first direction to enter into detachable engagement with the receptacle at a retention position relative to the receptacle, the first direction being an insertion direction defined by a first axis and a first plane;
wherein the main housing comprises a first portion, a second portion, and a peripheral portion interconnecting the first portion and the second portion which cooperate to define an internal compartment for accommodating items including circuitries, components and/or mechanisms;
wherein the attachment arrangement comprises a stop mechanism which is operable between an actuated state and a de-actuated state, and a de-actuation mechanism which is operable to de-actuate the stop mechanism;
wherein the stop mechanism is configured to impede movement of the main housing in a withdrawal direction relative to the second part when in the actuated state, the withdrawal direction being opposite to the insertion direction;
wherein the stop mechanism is configured to not to impede movement of the main housing in the withdrawal direction when in the de-actuated state, and the stop mechanism is in the de-actuated state when de-actuated; and
wherein the stop mechanism is configured to be de-actuated by application of a de-actuation force through the main housing to operate the de-actuation mechanism, the de-actuation force being in the insertion direction.

2. The apparatus of claim 1, wherein the stop mechanism is configured to operate in the actuated state and is to remain in the actuated state as a natural state unless and until the de-actuation force is applied to operate the de-actuation mechanism to de-actuate the stop mechanism.

3. The apparatus of claim 1, wherein the de-actuation mechanism is operable in an actuation state or a non-actuation state, wherein the de-actuation mechanism is configured to de-actuate the stop mechanism when in the actuation state, and wherein the de-actuation mechanism is configured to permit the stop mechanism to operate in the actuated state or in the de-actuated state when in the non-actuation state.

4. The apparatus of claim 3, wherein the de-actuation mechanism is configured to operate in the non-actuation state and is to remain in the non-actuation state as a natural state unless and until acted on by the de-actuation force, and wherein the de-actuation mechanism is configured to operate in the actuation state when acted on by the de-actuation force.

5. The apparatus according to claim 1, wherein the stop mechanism is internally set to operate in the activated state and to remain in the activated state as a natural state absent intervention by an external force, and wherein the de-actuation mechanism is internally set to operate in the non-actuation state and to remain in the non-activation state as a natural state absent intervention by an external force.

6. The apparatus according to claim 5, wherein the stop mechanism is internally set to operate in the activated state and to remain in the activated state by a state setting device, and the wherein the de-actuation mechanism is internally set to operate in the non-actuation state and to remain in the non-activation state by the state setting device.

7. The apparatus according to claim 6, wherein the state setting device is configured to urge the stop mechanism to move to the actuation state and which is configured to urge the de-actuation mechanism to move to the non-actuation state by the stop mechanism.

8. The apparatus according to claim 1, wherein the stop mechanism is internally set to operate in the activated state and to remain in the activated state as a natural state absent intervention by an external force, and wherein the de-actuation mechanism is internally set to operate in the non-actuation state and to remain in the non-activation state as a natural state absent intervention by an external force.

9. The apparatus according to claim 1, wherein the stop mechanism comprises a stop member which is movable between a clearance state which is an extended state and an impeding state which is a retracted state, and wherein the stop member is under an urging force to move towards the impeding state.

10. The apparatus according to claim 9, wherein the stop member is configured to urge the de-actuation mechanism to move towards the non-actuation state when the stop member is in the clearance state.

11. The apparatus according to claim 1, wherein the de-actuation mechanism comprises a pivot arm having a first arm portion, a second portion and a hinge axis intermediate the first arm portion and the second arm portion; wherein the de-actuation mechanism is rotatable about the hinge axis between a first angular position corresponding to the non-actuation state and a second angular position corresponding to the actuation state; and wherein the stop mechanism is moved into the de-actuation state when the pivot arm is moved to the actuation state.

12. The apparatus according to claim 1, wherein an access aperture is defined on a portion of the peripheral portion of the main housing, the portion of the peripheral portion being orthogonal to the insertion direction; and wherein the de-actuation mechanism is configured to be de-actuated by application of the de-actuation force through the access aperture.

13. The apparatus of claim 12, wherein the access aperture is configured for access by a de-actuation tool which is to enter the main housing in the insertion direction to move the de-actuation mechanism to the actuation state.

14. The apparatus according to claim 1, wherein a plurality of stop parts is distributed around the peripheral portion of the main housing, wherein the plurality of stop parts is configured for making stop engagement with a corresponding plurality of corresponding stop parts on the receptacle on arriving at the retention position; and wherein the stop parts and the corresponding stop parts cooperate to stop movement in away from the receptacle in a direction which is orthogonal to the first plane.

15. The apparatus according to claim 1, wherein a plurality of engagement parts is distributed around the peripheral portion of the main housing, and wherein the plurality of engagement parts is configured for making frictional engagement with a corresponding plurality of corresponding engagement parts on the receptacle on arriving at the retention position.

16. The apparatus according to claim 15, wherein the engagement parts are configured such that the frictional engagement is to bring the main housing into the compressive contact with the receptacle and is prevented from moving away from the receptacle in a direction orthogonal to the first plane.

17. The apparatus according to claim 1, wherein the main housing is configured to be released from the receptacle by moving in the withdrawal direction when the stop mechanism is de-actuated; and wherein the main housing is not detachable from the receptacle when the when the stop mechanism is actuated.

18. The apparatus according to claim 1, wherein the apparatus is configured as an audio cartridge comprising an audio transducer.

19. An assembly comprising the apparatus according to claim 1 as a first part and the receptacle as a second part in an assembled configuration, wherein the first part is in the retention position relative to the second part, and wherein the first part and second part are in compressive contact by operation of a frictional engagement system comprising corresponding engagement parts which are distributed around the peripheral portion of the main housing.

20. An assembly of claim 19, whereon the second part comprises a base portion and a peripheral portion, and wherein the second part is configured as a bracket to embrace the peripheral portion of the first part.
